(19) United States
(12) Patent Application Publication
(10) Pub. No.: US 2008/0179761 A1
(43) Pub. Date: Jul. 31, 2008

(54) SEMICONDUCTOR PACKAGE HAVING EVAPORATED SYMBOLIZATION

(75) Inventor: Kazuaki Ano, Hayami-gun (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/013,599

(22) Filed: Jan. 14, 2008

Related U.S. Application Data
(60) Provisional application No. 60/886,829, filed on Jan. 26, 2007.

(51) Int. Cl. H01L 23/544; B41F 23/04

(52) U.S. Cl. 257/797; 101/487; 257/E23.179

(57) ABSTRACT

The package (105) of a semiconductor chip has a surface (105a) of optical reflection and color, and is substantially free of indentations; the material of the package may be selected from a group consisting of polymers, molding compound, ceramics, metals, and semiconductors. The surface includes symbols, which contrast optically with the surface. The symbols include lines of approximately circular vapor-deposited spots (110) of ink particles. The spots have a diameter and a thickness of substantially bell-shaped distribution across the diameter; the spots may also overlap.

### FIELD OF THE INVENTION

The present invention is related in general to the field of semiconductor devices and processes and more specifically to the structure and fabrication method of the symbolization on thin semiconductor packages.

### DESCRIPTION OF THE RELATED ART

In the process flow of packaging semiconductor chips into complete devices, the typically last step is the symbolization of the device, which records the information the user needs to know for proper identification and usage of the device. Examples are device type and model, manufacturer, key performance characteristics, and dates. Among the favorite symbolization techniques are stamping with ink for larger letter sizes, and scribing with lasers for smaller letter sizes. Laser scribing is especially favored for plastic packages, which are commonly fabricated by transfer molding technology. In the molding technology, the compound is selected to obtain a shiny surface after polymerization so that the surface has good reflection of visible light.

In the inking technique, it is the color difference between the ink and the package surface, which makes the symbolization legible. In the laser scribing technique, it is the reflection difference for visible light, which makes the symbolization legible. The laser beam digs a groove into the encapsulation resin, which renders the affected zones with a poor light reflection.

The ongoing market trend towards smaller and thinner semiconductor components is now demanding packages so thin that the loops of the bonding wires, which are used to electrically interconnect the semiconductor chip with other part of the device inside the package (such as metal leadframe segments), come in close proximity to the package surface. In these cases, there is a high risk that the scribing laser beam digs a groove all the way through the thin encapsulation material to expose the bond wire loop tops. Whenever this damage happens, the device is useless.

### SUMMARY OF THE INVENTION

Applicant recognizes the need for a new approach to symbolizing semiconductor devices. The new technology is based on evaporation and vapor deposition and is thus non-destructive to the surface-to-be-symbolized. It further uses a method, which is fast, computer programmable, flexible, and low cost. The method produces symbols, which exhibit small feature sizes, but are clearly legible. The method can further be adapted for a variety of product materials such as plastics, ceramics, metals, paper, or semiconductor materials; it can be used on different surface conditions such as smooth, polished, or rough; and it can be modified for creating symbols of different colors and light reflections.

One embodiment of the invention is a packaged semiconductor chip, wherein the package has a surface of optical reflection and color, and is substantially free of indentations; the material of the package may be selected from a group consisting of polymers, molding compound, ceramics, metals, semiconductors. The surface includes symbols, which contrast optically with the surface. The symbols include lines of approximately circular vapor-deposited spots of ink particles. The spots have a diameter and a thickness of substantially bell-shaped distribution across the diameter.

With the evaporation source at a certain distance from the receiving surface, the thickness in the substantially bell-shaped distribution across the deposited spots decreases about 2% from the spot center value after a radius equal to about 10% of the evaporation distance. Further, the thickness decreases to about 60% of the spot center value after a radius from the center of approximately 50% of the evaporation distance.

Another embodiment of the invention is a method for symbolizing a semiconductor device with a packaged chip. The package, made of a plastic, ceramic, metallic or semiconductor material, has a first surface of optical reflection and color, and is substantially free of indentations. A film with second and third surfaces is filled with ink particles optically contrasting with the package surface. The film is placed substantially parallel to the first surface so that the second surface is at a distance from the first surface.

A laser, movable in x- and y-directions and programmed for sending power pulses at intervals, is focused the on the third surface to heat the film volume under the focus to a temperature sufficiently high to evaporate ink particles from the second film surface towards the first surface. The pulse duration is selected so that the evaporated ink forms an approximated circle on the first surface, the circle having a diameter and a thickness of substantially bell-shaped distribution across the diameter. While the temperature of the first surface is controlled so that the impinging ink particles stick to the first surface to form the spots, the laser is scanned in x- and y-directions. The pulses are operated at the programmed intervals so that ink particles are evaporated from each heated film volume onto the first surface. The sequence of vapor-deposited spots results in symbols optically contrasting with the first surface.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows a schematic cross section of an embodiment of the invention on a wire bonded flip-chip semiconductor device with a molded package.

FIG. 2 is a top view of a semiconductor device illustrating schematically examples of symbols composed of ink dots vapor-deposited by the pulsed laser technique of the invention.

FIG. 3 is a simplified, schematic top view of a semiconductor device depicting examples of symbols as evaporated by the method of the invention.

FIG. 4 depicts an evaporation distribution of the normalized ink dot thickness (d/dₒ) as a function of the distance ratio l/h of substrate and source.

FIG. 5 illustrates schematically the fabrication arrangement for the evaporation method of the invention.

FIG. 6 shows schematically the evaporation method of the invention. Illustrated is a cross section of an ink-loaded film extended over the package surface of a semiconductor device, while a laser pulse hits a film spot.

FIG. 7 depicts schematically the heating of a film volume by a laser pulse with the resulting evaporation of ink from the film onto the device package surface to form an ink dot on the surface.

### DETAILED DESCRIPTION OF THE PREFERRED EMBODIMENTS

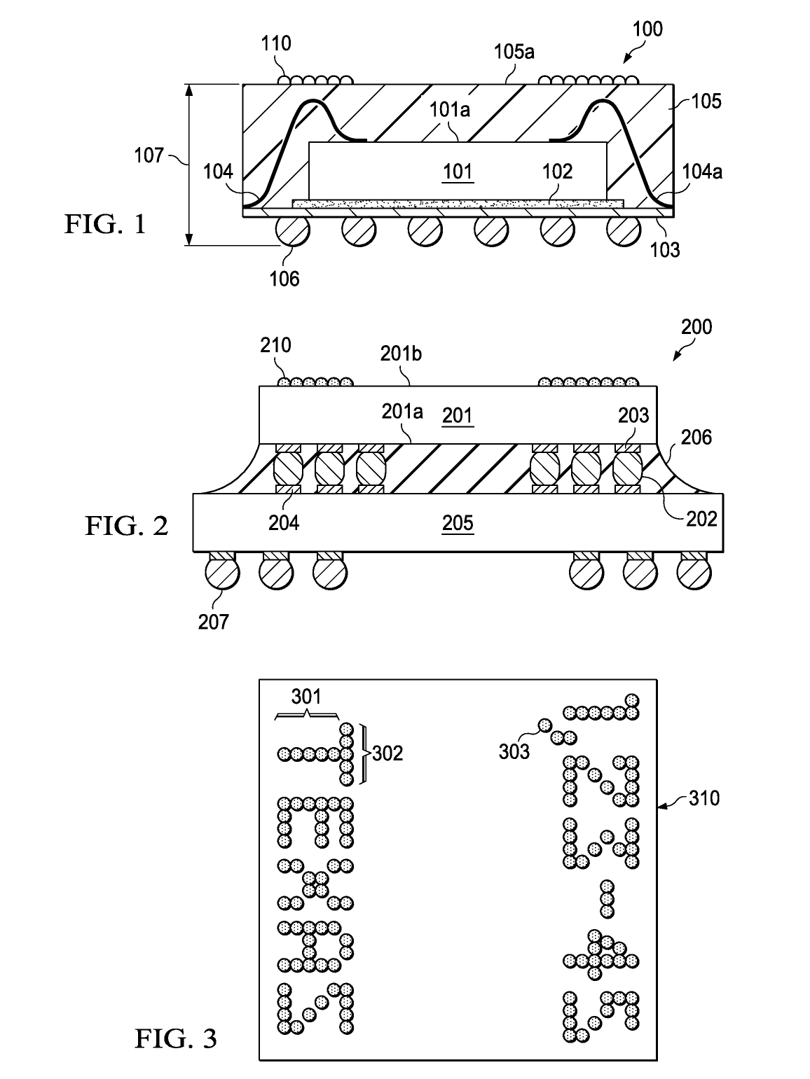

The cross section of FIG. 1 illustrates an embodiment of the invention on a schematic semiconductor device generally designated 100. The device has a semiconductor chip 101 attached by adhesive 102 to substrate 103. Chip 101 has an area 101a, which includes the active electrical components (and is thus sometimes referred to as the active area, or active surface). The active area 101a of chip 101 is electrically connected by bond wires 104 to substrate 103. Bond wires 104 form loops 104a. Substrate 103 has solder balls 106 attached in order to provide attachment to external parts.

Chip 101, bond wires 104 and portions of substrate 103 are encapsulated in a package of plastic material 105, preferably a thermoset molding compound. Alternatively, the package may be made of a thermoplastic polymer, or a ceramic material, or the package may even be a metallic encapsulation. Whatever the encapsulating compound, the package material forms an outer surface 105a over the active chip area, which is substantially free of indentations; surface 105a is substantially flat throughout. Further, surface 105a has a certain optical reflection and a certain color. As an example, surface 105a may be dark (for instance black) and shiny; or it may be light (for instance white) and matte; or any other combination.

Alternatively, package 105 may encapsulate assemblies other than a wire-bonded semiconductor chip; examples include a flip-chip assembly, or an assembly including more than one semiconductor chip, or an assembly of chips and passive electrical components.

Surface 105a includes the symbolization 110 of the device. The symbolization preferably may include numbers, letters, trademarks, or usage codes, and may refer to device type, manufacturer, country of origin, year of production, and other information. In order to be clearly legible, the device symbolization must have sufficient contrast in color or reflectivity, or both, compared to surface 105a. Symbolization 110 is produced by the evaporation technique (see below), avoiding the customary symbolization techniques of stamping with ink and of laser scribing (scratching).

The ongoing miniaturization trend for semiconductor devices requires often tiny symbols, which makes the inking technique unsatisfactory for symbolization, because it produces un-crisp, fuzzy symbols. Furthermore, recent applications such as hand-held products demand semiconductor components with very tight boundaries for the overall thickness 107, preferably within less than 1 mm. Because of this constraint, only very thin encapsulation material can be afforded to cover the wire loops 104a. Consequently, surface 105a has to remain substantially free of indentations and it is no longer permissible to employ a laser beam to scribe or indent surface 105a, because the trenches necessarily dug by the laser may expose the wire loops.

FIG. 1 illustrates symbols 110 on surface 105a, which are optically contrasting with surface 105a with regard to color or reflectivity, or both. Examples of the symbols 110 are depicted in the top view of FIG. 3; the examples include numbers and letters.

FIG. 2 shows another embodiment of the invention for a semiconductor device, generally designated 200, with flip-assembled chip 201. The chip surface 201a with the electrically active components (the “active” chip surface) has contact pads 203, which are connected by metal bumps 202 to the respective contact pads 204 of substrate 205. Metal bumps 202 may either be reflow bodies, usually tin-based solder balls, or bumps made of metals or alloys, which do not reflow at semiconductor assembly temperatures. Preferred metal include gold, copper or alloys thereof. The gap between the chip and the substrate and the space between the contact joints is preferably filled with plastic material 206 in order to mitigate thermomechanical stress. Substrate 205 may have solder balls 207 attached in order to provide attachment to external parts.

In FIG. 2, the chip surface without electrically active components is designated 201b (the “passive” chip surface). As the surface of a semiconductor chip, surface 201b is substantially free of indentations; it is flat throughout. Further, surface 201b has a certain optical reflection and a certain color. As an example, surface 201b may have the matte, silver-gray appearance of lapped silicon.

Surface 201b includes the symbolization 210 of the device. The symbolization preferably may include numbers, letters, trademarks, or usage codes, and may refer to device type, manufacturer, country of origin, year of production, and other information. In order to be clearly legible, the device symbolization has to have sufficient contrast in color and/or reflectivity compared to surface 201b. Symbolization 210 is produced by the evaporation technique (see below), avoiding the inferior customary stamping method.

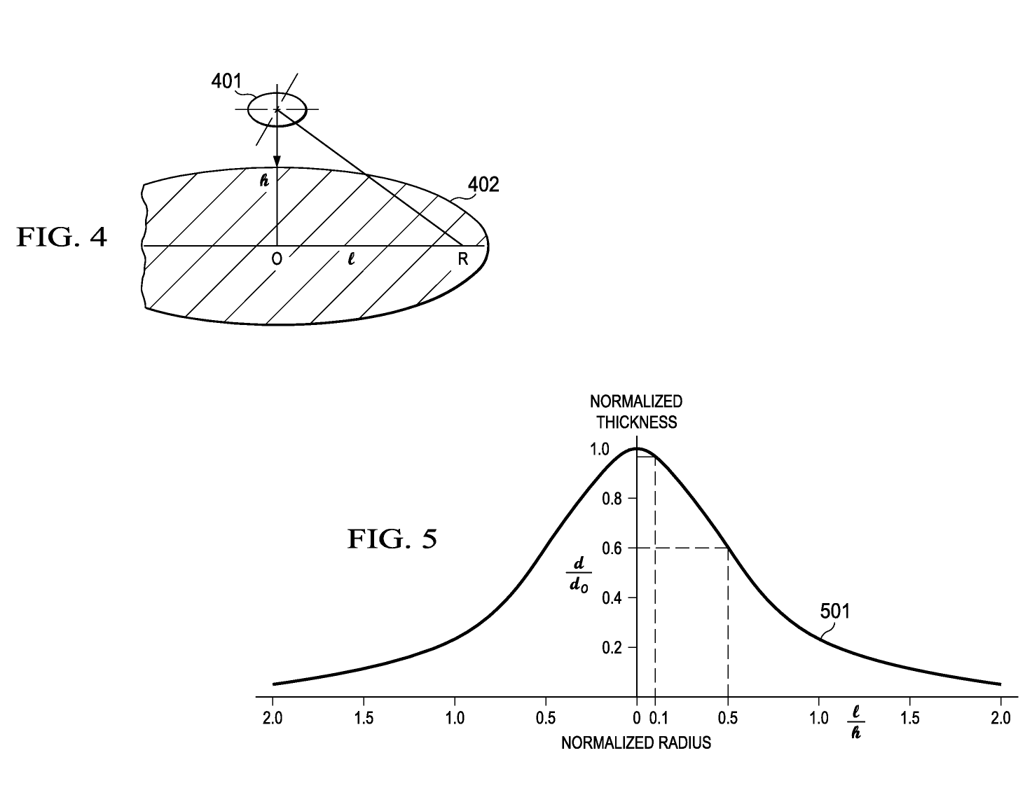

FIG. 3 is a top view of surfaces such as surface 105a in FIG. 1 or surface 201b of FIG. 2; the surface in FIG. 3 is designated 310. As FIG. 3 shows, the symbols (designated 110 in FIG. 1 and 210 in FIG. 2) include numbers, letters, and mathematical symbols. Each symbol consists of lines, such as lines 301 and 302, of approximately circular, equally spaced and often partially overlapping spots 303. Other spots are located in more isolated manner. The spots 303 have a certain diameter and are made of vapor-deposited particles such as ink particles. The particles are compiled to a height over surface 310 to give the spots a thickness, which has a substantially bell-shaped distribution across the diameter. More detail is described in FIGS. 4 and 5.

The particles, which make up the spots, are preferably ink particles, since the color of the ink can be selected to contrast strongly with the color of the background surface. As an example, the particles to create dots 303 in FIG. 3 are black, in contrast to the whitish surface 310, which may be the passive surface of a semiconductor chip. As another example, the ink particles can be selected to have a low light reflectivity in contrast to the shiny surface of a plastic epoxy-based molding compound. As another example, for black-colored molding compounds, the preferred color for ink particles may be white, yellow or another light color.

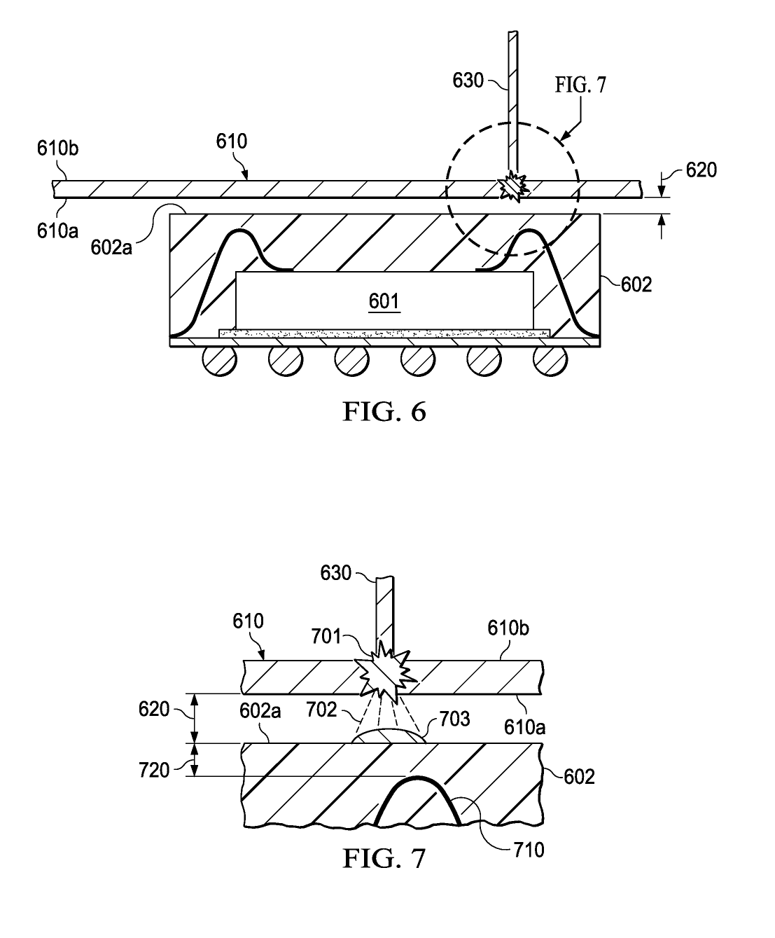

A simplified and schematic illustration of the evaporation method used in this invention is depicted in FIG. 4 (more detail is FIGS. 6 and 7) and the resulting thickness distribution across an evaporated spot is shown in FIG. 5. In the fabrication arrangement of FIG. 4, the small-area evaporation source is designated 401, and the receiving plane surface, parallel to source 401, is designated 402. It is preferred that plane 402 is cooled enough to let the impinging material stick and thus prevent re-evaporation. The shortest distance between source 401 to the receiving surface 402 is h. Due to symmetry considerations, the spot evaporated on plane 402 is substantially circular, so that the hit point at the shortest distance h may be called the center or origin O of the circle, and the respective distance from O the radius l with endpoint R.

Under the condition that the mean free path of the evaporated material is large compared to h. The local thickness of the deposited material may by called d; it has its highest value dₒ at point O, closest to the evaporation source 401. The thickness d normalized to dₒ is d/dₒ (dimensionless).

The thickness d varies from center O to point R at radial distance l. Radius l may be normalized to evaporation distance h, resulting in l/h, which is dimensionless. For the small-area source 401, the thickness variation is as follows:

d/dₒ=1/[1+(l/h)²]².

This thickness distribution is plotted as curve 501 in FIG. 5.

Curve 501 indicates that the spot thickness d drops from the value dₒ at the center to about 60% (d/dₒ=0.6) of that value after a radius l from the center of approximately 50% of the evaporation distance h (l/h=0.5). Another characteristic of curve 501 is that the spot thickness d decreases about 2% from the center value dₒ (d/dₒ=0.98) after a radius l from the center equal to approximately 10% of the evaporation distance h (l/h=0.1).

When the mean free path of the evaporated particles is comparable to h, or smaller than h, an overall bell-shaped thickness distribution across the spot diameter still remains, but the specific values of the curve in FIG. 5 are may be changed.

Another embodiment of the invention is a method for symbolizing a semiconductor device; some steps of the method are illustrated in FIGS. 6 and 7. The example of the semiconductor device selected in FIG. 6 is similar to the device of FIG. 1; in other examples, the device may be similar to the device in FIG. 2. The device includes an assembled and packaged semiconductor chip 601. The package 602 has a first surface 602a of a certain optical reflection and color. Surface 602a further is substantially free of indentations. Surface 602a may be the surface of a plastic, ceramic, or metallic encapsulation material, or it may be the passive surface of a semiconductor chip.

In the next process step, a film 610 is provided, which has a second surface 610a and a third surface 610b. Film 610 is preferably made of a chemically inert plastic material, such as a polyimide-based compound. The film has preferably a thickness between 0.05 and 0.1 mm. In spite of its thinness, the film is mechanically strong so that it can be unfolded and held under some tension to form a flat plane without excessive sagging or rupturing, at least over the area of surface 602a of the semiconductor device.

Film 610 is filled with ink particles selected so that they optically contrast with the package surface 602a. The ink particles may contrast in color with the first surface color, or they may contrast in reflection of visible light with the first surface reflection; the ink particles may also contrast in both color and reflection with the package surface.

Alternatively, the film may be filled with particles other than ink, as long as the particles can be evaporated by the laser and can create symbols with an optical contrast (in color or in reflectivity, or both) on the surface-to-be-symbolized. Such particles may include atoms, or inorganic or organic molecules, which absorb or reflect light of specific wave lengths, or create light scattering centers.

As illustrated in FIG. 6, film 610 is placed substantially parallel to first surface 602a so that second surface 610a is at a distance 620 from first surface 602a. Distance 620 is often referred to as the evaporation distance. Preferably, distance 620 between the first surface 602a and the film 610 (second surface 610a) is between about 0.05 and 0.15 mm; more preferably, distance 620 is about 0.1 mm. For some devices or film and ink selections, it is preferred to reduce distance 620 so that it approaches zero and film 620 rests on surface 602a.

Next, a laser is provided, which is movable in x- and y-directions and can be programmed for sending power pulses at intervals, wherein each pulse has a duration. A preferred choice is a YAG laser which has a substantially circular focus between about 0.08 and 0.12 mm diameter, preferably 0.10 mm. This diameter provides both a sufficiently large evaporation surface (and volume) and a small spot diameter. The laser has preferably a pulse duration between about 0.1 and 0.01 ms, which corresponds to an operation between 10 kHz and 100 kHz.

The laser beam 630 is focused on the third surface 610b, as shown in FIG. 6, in order to heat the film volume 701 under the focal area, as shown in FIG. 7. The focus is substantially circular and has preferably a diameter between about 0.08 and 0.12 mm, more preferably about 0.1 mm for machine sorting of the package. The temperature of the heated film volume is preferably kept between about 70 and 150° C. At these temperatures, the evaporation rate is sufficiently high to evaporate ink particles from the second surface 610a towards the first surface 602a without significant chance of chemical interaction between the evaporant and the film material.

FIG. 7 schematically illustrates the evaporated ink particles 702 and their accumulation as a spot 703 on surface 602a. During the evaporation process, package material 602 is preferably cooled to control the temperature of first surface 602a so that the impinging ink particles stick to the first surface to form spots 703 without significantly re-evaporating from the surface. A surface temperature between about 5 and 20° C. is acceptable; for some environments, it is preferable to operate in dry nitrogen ambient in order to prevent condensation of moisture on the package surface.

In the laser operation, the pulse duration is selected so that the evaporated ink 702 forms a spot 703 with an approximate circle on first surface 602a. The circle has a diameter (and a radius) and a thickness of substantially bell-shaped distribution across the diameter (detail see FIG. 5). Alternatively, a laser with non-pulsing (continuous) operation may be used.

In consecutive process steps, the laser is scanned in a plane parallel to the package surface (first surface), while the pulses are operated at the programmed intervals so that ink particles are evaporated from each heated film volume 701 onto first surface 602a. The sequence of deposited spots 703 is rapid and results in symbols made of ink particles contrasting optically with first surface 602a. Preferably, the optical contrast involves both color and light reflection. Examples of symbols are depicted in FIG. 3. In many symbols, the evaporated spots are close together so that the spots partially overlap.

FIG. 7 illustrates a portion of a device, for which the application of the new symbolization method is especially beneficial. In the depicted device portion, the loop of a bonding wire 710 is close to surface 602a. Any surface damage, such as a scratch or an indentation, to the package material in the remaining thin layer 720 would put the device at risk. The evaporation by the new method, however, provides device symbolization without any harm to package surface 602a.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description.

As an example, the symbolization method may be used on devices other than semiconductor components, since the method is non-destructive to the surface-to-be-symbolized. As another example, the method can be adapted for a variety of product materials such as plastics, ceramics, metals, paper, or semiconductor materials; it can be used on different surface conditions such as smooth, polished, or rough; and it can be modified for creating symbols of different colors and light reflections.

As another example, the symbolization method may be used on packages encapsulating more than one chip, other electrical components, and components assembled with wire bonding or flip-chip techniques. As another example, a laser with non-pulsing operational mode may be employed.

Another example is a film, which is filled with particles other than ink, which can be evaporated by the laser and can create symbols with an optical contrast (in color or in reflectivity, or both) on the surface-to-be-symbolized. Such particles may include atoms or inorganic or organic molecules.

It is therefore intended that the appended claims encompass any such modifications or embodiments.

I claim:

1. An apparatus comprising:
a semiconductor chip in a package;
the package having a surface of optical reflection and color and substantially free of indentations;
the surface including symbols optically contrasting with the surface; and
the symbols including lines of approximately circular vapor-deposited spots of particles, the spots having a diameter and a thickness of substantially bell-shaped distribution across the diameter.

2. The device according to claim 1 wherein the package has a material selected from a group consisting of polymers, molding compounds, ceramics, metals, and semiconductors.

3. The device according to claim 1 wherein the package surface is a passive surface of a chip.

4. The device according to claim 1 wherein the particles include ink particles.

5. The device according to claim 1 wherein the optical contrast includes a color difference.

6. The device according to claim 1 wherein the optical contrast includes a difference in reflectivity of light.

7. The device according to claim 1 further including bond wire loops providing electrical connections to the chip.

8. The device according to claim 1 wherein the symbols include numbers, letters, and trademarks.

9. The device according to claim 1, wherein adjacent spots partially overlap.

10. A method comprising:
providing a semiconductor device including a packaged chip, the package having a first surface of optical reflection and color, the surface being substantially free of indentations;
providing a film having second and third surfaces, the film filled with ink particles optically contrasting with the package surface;
placing the film substantially parallel to the first surface so that the second surface is at a distance from the first surface;
providing a laser movable in a plane parallel to the first surface and programmed for sending power pulses at intervals, each pulse having a duration;
focusing the laser beam on the third surface to heat a film volume under the focus to a temperature sufficiently high to evaporate ink particles from the second film surface towards the first surface;
selecting the pulse duration so that the evaporated ink forms an approximately circular spot on the first surface, the spot having a diameter and a thickness of substantially bell-shaped distribution across the diameter;
controlling the temperature of the first surface so that the impinging ink particles stick to the first surface to form the spots; and
scanning the laser while operating the pulses at the programmed intervals so that ink particles are evaporated from each heated film volume onto the first surface, whereby the sequence of deposited spots results in symbols optically contrasting with the first surface.

11. The method according to claim 10 wherein the thickness in the substantially bell-shaped distribution decreases about 2% from the spot center value after a radius equal to about 10% of the evaporation distance.

12. The method according to claim 10 wherein the thickness in the substantially bell-shaped distribution decreases to about 60% of the spot center value after a radius from the center of approximately 50% of the evaporation distance.

13. The method according to claim 10 wherein the spots partially overlap.

14. The method according to claim 10, wherein the package surface is the surface of a plastic or ceramic encapsulation material, or the passive surface of a semiconductor chip.

15. The method according to claim 10 wherein the ink particles contrast in color with the first surface color.

16. The method according to claim 10 wherein the ink particles contrast in reflection of visible light with the first surface reflection.

17. The method according to claim 10 wherein the film includes a polyimide-based material and has a thickness in the range from about 0.05 to 0.1 mm.

18. The method according to claim 10 wherein the distance between the first surface and the film is about 0.05 to 0.15 mm.

19. The method according to claim 10 wherein the distance between the first surface and the film is about 0.1 mm.

20. The method according to claim 10 wherein the distance between the first surface and the film approaches zero so that the film rests on the surface.

21. The method according to claim 10 wherein the laser includes a YAG laser having a substantially circular focus between about 0.08 and 0.12 mm diameter and a pulse length between about 0.1 and 0.01 ms, corresponding to an operation at 10 kHz and 100 kHz.

22. The method according to claim 10 wherein the temperature of the heated film volume is between about 70 and 150° C.

23. The method according to claim 10 wherein the temperature of the first surface is controlled between about 5 and 20° C.
